(19) United States
(12) Patent Application Publication
(10) Pub. No.: US 2025/0046114 A1
(43) Pub. Date: Feb. 6, 2025

(54) FINGERPRINT SENSOR AND DISPLAY DEVICE INCLUDING THE SAME

(71) Applicant: SAMSUNG DISPLAY CO., LTD., YONGIN-SI (KR)

(72) Inventors: HYANG A PARK, Yongin-si (KR); SOO YEONG HONG, Yongin-si (KR); TAE KYUNG AHN, Yongin-si (KR); KANG BIN JO, Yongin-si (KR)

(21) Appl. No.: 18/660,995

(22) Filed: May 10, 2024

(30) Foreign Application Priority Data
Aug. 3, 2023 (KR) 10-2023-0101476

(51) Int. Cl. G06V 40/13; H10K 39/32; H10K 39/34; H10K 39/38

(52) U.S. Cl. CPC G06V 40/1318; H10K 39/32; H10K 39/34; H10K 39/38

(57) ABSTRACT

A fingerprint sensor comprises a read-out line disposed on a substrate and extending in a first direction, a light receiving element disposed on the read-out line, a first sensor transistor controlling a sensing current based on a voltage of a sensor node that is a first electrode of the light receiving element, a second sensor transistor supplying a reset voltage to the sensor node based on a reset signal, and a third sensor transistor electrically connecting a first electrode of the first sensor transistor with the read-out line based on a gate signal. The fingerprint sensor further includes a power line disposed on a layer between the second sensor transistor and the read-out line and extending in the first direction. The power line overlaps the read-out line.

### CROSS-REFERENCE TO RELATED APPLICATION

This application claims priority from Korean Patent Application No. 10-2023-0101476, filed on Aug. 3, 2023, in the Korean Intellectual Property Office and all the benefits accruing therefrom under 35 U.S.C. 119, the contents of which in its entirety are herein incorporated by reference.

### BACKGROUND

### 1. Technical Field

The present disclosure relates to a fingerprint sensor and a display device including the same.

### 2. Description of the Related Art

Many forms of electronics have display devices. Examples include smart phones, digital cameras, laptop computers, navigators and smart televisions. Some display devices have pixels with self-emitting light elements which display images without a backlight unit. Some display devices further include an optical sensor for sensing light and a fingerprint sensor for sensing a fingerprint. Attempts have been made to improve display devices, but these attempts have drawbacks.

### SUMMARY

According to an embodiment, a fingerprint sensor comprises a read-out line disposed on a substrate and extended in a first direction, a light receiving element disposed on the read-out line, a first sensor transistor configured to control a sensing current based on a voltage of a sensor node that is a first electrode of the light receiving element, a second sensor transistor configured to supply a reset voltage to the sensor node based on a reset signal, a third sensor transistor electrically connecting a first electrode of the first sensor transistor with the read-out line based on a gate signal, and a power line disposed on a layer between the second sensor transistor and the read-out line and extended in the first direction, overlapping the read-out line.

The power line may be direct current power line that comprises a reset voltage line supplying the reset voltage or a low potential line connected to the second electrode of the light receiving element to supply a low potential voltage.

A semiconductor area of each of the first sensor transistor and the third sensor transistor may include a silicon-based material, and a semiconductor area of the second sensor transistor may include an oxide-based material.

The third sensor transistor may include a third-first sensor transistor and a third-second sensor transistor, which are connected in series between the first electrode of the first sensor transistor and the read-out line.

The fingerprint sensor may further comprise a first active layer disposed on the substrate, a first gate layer disposed on the first active layer, a second gate layer disposed on the first gate layer, a second active layer disposed on the second gate layer, a third gate layer disposed on the second active layer, a first source metal layer disposed on the third gate layer, a second source metal layer disposed on the first source metal layer, comprising the power line, and a third source metal layer disposed on the second source metal layer, comprising the read-out line.

The fingerprint sensor may further comprise a read-out electrode disposed in the first source metal layer to electrically connect the read-out line with the third sensor transistor.

The fingerprint sensor may further comprise a sensor node electrode disposed in the second source metal layer, corresponding to the sensor node, and a sensor connection electrode disposed on the first source metal layer, electrically connecting a gate electrode of the first sensor transistor with the sensor node electrode.

The fingerprint sensor may further comprise a reset voltage line including a first portion disposed in the second source metal layer and extended in the first direction, a second portion disposed in the first source metal layer and connected to the first portion and extended in a second direction crossing the first direction and a third portion disposed in the second source metal layer and electrically connected between the second portion and the first electrode of the second sensor transistor.

The third portion of the reset voltage line may overlap a semiconductor area of the second sensor transistor.

A semiconductor area of the first sensor transistor may be disposed in the first active layer, and a semiconductor area of the second sensor transistor may be disposed in the second active layer.

The fingerprint sensor may further comprise a gate line disposed in the first gate layer to supply the gate signal, and a reset signal line disposed in the third gate layer to supply the reset signal.

According to an embodiment, a fingerprint sensor comprises a light receiving element disposed on a substrate, a first sensor transistor configured to control a sensing current based on a voltage of a sensor node that is a first electrode of the light receiving element, a second sensor transistor configured to supply a reset voltage to the sensor node based on a reset signal, a third sensor transistor electrically connecting a first electrode of the first sensor transistor with a read-out line based on a gate signal, a first active layer disposed on the substrate, comprising a semiconductor area of the first sensor transistor, a first gate layer disposed on the first active layer, comprising a gate electrode of the first sensor transistor, a second gate layer disposed on the first gate layer, a second active layer disposed on the second gate layer, comprising a semiconductor area of the second sensor transistor, a third gate layer disposed on the second active layer, comprising a gate electrode of the second sensor transistor, a first source metal layer disposed on the third gate layer, a second source metal layer disposed on the first source metal layer, comprising the power line, and a third source metal layer disposed on the second source metal layer, comprising the read-out line overlapped with the power line.

The power line may be a direct current power line comprising a reset voltage line configured to supply the reset voltage or a low potential line connected to a second electrode of the light receiving element to supply a low potential voltage.

A semiconductor area of each of the first sensor transistor and the third sensor transistor may include a silicon-based material, and a semiconductor area of the second sensor transistor may include an oxide-based material.

The third sensor transistor may include a third-first sensor transistor and a third-second sensor transistor, which are connected in series between the first electrode of the first sensor transistor and the read-out line.

The fingerprint sensor may further comprise a read-out electrode disposed in the first source metal layer to electrically connect the read-out line with the third sensor transistor.

The fingerprint sensor may further comprise a sensor node electrode disposed in the second source metal layer, corresponding to the sensor node, and a sensor connection electrode disposed in the first source metal layer, electrically connecting the gate electrode of the first sensor transistor with the sensor node electrode.

According to an embodiment, a display device comprises a read-out line disposed on a substrate and extended in a first direction, a fingerprint sensor disposed on the read-out line, comprising a light receiving element, and a pixel including a light emitting element disposed on the same layer as the light receiving element. The fingerprint sensor further comprises a first sensor transistor configured to control a sensing current based on a voltage of a sensor node that is a first electrode of the light receiving element, a second sensor transistor configured to supply a reset voltage to the sensor node based on a reset signal, a third sensor transistor electrically connecting a first electrode of the first sensor transistor with the read-out line based on a gate signal, and a power line disposed on a layer between the second sensor transistor and the read-out line and extended in the first direction, overlapping the read-out line.

The display device may further comprise a first active layer disposed on the substrate, a first gate layer disposed on the first active layer, a second gate layer disposed on the first gate layer, a second active layer disposed on the second gate layer, a third gate layer disposed on the second active layer, a first source metal layer disposed on the third gate layer, a second source metal layer disposed on the first source metal layer, comprising the power line, and a third source metal layer disposed on the second source metal layer, comprising the read-out line.

The display device may further comprise a data line disposed on the second source metal layer and extended in the first direction, supplying a data voltage to the pixel.

In the fingerprint sensor and the display device including the same according to the embodiments, the display device may include a low potential line or a reset voltage line, which is disposed below a read-out line to overlap the read-out line, to avoid coupling between a data line and the read-out line, thereby improving sensitivity.

In accordance with one or more embodiments, a fingerprint sensor includes a read-out line; a light receiving element; a reset signal line to reset a sensor node; and a power line which overlaps the read-out line to shield the read-out line from at least one signal line of a pixel disposed adjacent to the fingerprint sensor. The at least one signal line may be a data line of the pixel. The reset signal line may be coupled to a reset transistor, and the power line may be disposed on a layer between the reset transistor and the read-out line. The power line may be a low potential power line which couples the low potential to the light receiving element and a light emitting element of the pixel. The power line may be a portion of a reset power line coupled to a transistor coupled to the reset signal line.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view illustrating a display device according to one embodiment;

FIG. 2 is a cross-sectional view illustrating a display device according to one embodiment;

FIG. 3 is a plan view illustrating a display unit of a display device according to one embodiment;

FIG. 4 is a block diagram illustrating a display panel and a display driver according to one embodiment;

FIG. 5 is a plan view illustrating an emission area and a sensor area of a display device according to one embodiment;

FIG. 6 is a circuit view illustrating a pixel of a display device according to one embodiment;

FIG. 7 is a cross-sectional view illustrating a pixel of a display device according to one embodiment;

FIG. 8 is a circuit view illustrating a fingerprint sensor of a display device according to one embodiment;

FIG. 9 is a layout view illustrating a fingerprint sensor of a display device according to one embodiment;

FIG. 10 is a cross-sectional view taken along line I-I′ of FIG. 9 according to an embodiment; and

FIG. 11 is a cross-sectional view taken along line II-II′ of FIG. 9 according to an embodiment.

### DETAILED DESCRIPTION OF THE DISCLOSURE

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

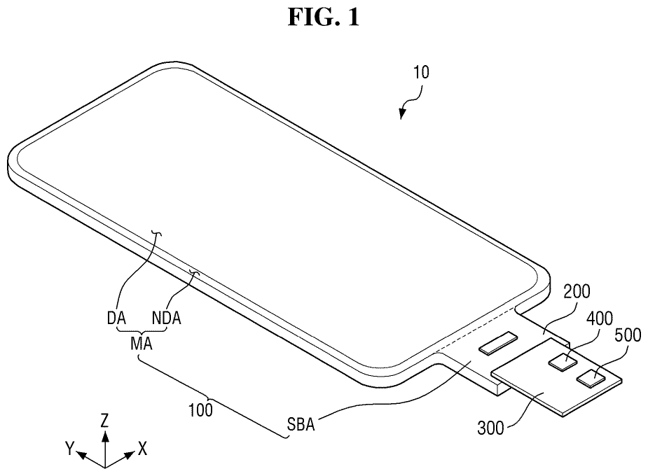

FIG. 1 is a perspective view illustrating a display device 10 according to one embodiment. The display device 10 may be applied to a portable electronic device such as a mobile phone, a smart phone, a tablet personal computer (PC), a mobile communication terminal, an electronic diary, an electronic book, a portable multimedia player (PMP), a navigator and an ultra mobile PC (UMPC). The display device 10 may also be applied to a television, a laptop computer, a monitor, a signboard or a display unit of Internet of things (IoT) device. The display device 10 may also be applied to a wearable device such as a smart watch, a watch phone, an eyeglasses-type display and a head mounted display (HMD).

The display device 10 may be formed to have a plane shape, for example, similar to a rectangular shape. For example, the display device 10 may have a plane shape similar to a rectangular shape having short sides in X-axis direction and long sides in Y-axis direction. Corner where the short sides of the X-axis direction and the long sides of the Y-axis direction meet may be rounded to have a predetermined curvature or, in other cases, may be formed at right angles. In some embodiments, the plane shape of the display device 10 may have other polygonal shapes, a circular shape or an oval shape.

Referring to FIG. 1, the display device 10 may include a display panel 100, a display driver 200, a circuit board 300, a touch driver 400 and a power supply unit 500.

The display panel 100 may include a main area MA and a sub-area SBA. The main area MA may include a display area DA having pixels for displaying an image and a non-display area NDA disposed near (or adjacent to) the display area DA. The display area DA may include pixels that emit light from a plurality of emission areas or a plurality of opening areas. For example, each pixel of the display panel 100 may include a pixel circuit including switching elements, a pixel defining layer defining an emission area or an opening area, and a self-light emitting element. For example, the self-light emitting element may include at least one of an organic light emitting diode including an organic light emitting layer, a quantum dot light emitting diode including a quantum dot light emitting layer, an inorganic light emitting diode including an inorganic semiconductor or a micro light emitting diode (micro LED), but is not limited thereto.

The non-display area NDA may be an outer area of the display area DA. The non-display area NDA may be an edge area of the main area MA of the display panel 100. The non-display area NDA may include a gate driver for supplying gate signals to gate lines, and fan-out lines connecting the display driver 200 with the display area DA.

The sub-area SBA may extend from one side of the main area MA. The sub-area SBA may include a flexible material capable of bending, folding, rolling and the like. For example, when the sub-area SBA is bent, the sub-area SBA may overlap the main area MA in a thickness direction (Z-axis direction). The sub-area SBA may include the display driver 200, and a pad portion connected to the circuit board 300. Optionally, the sub-area SBA may be omitted, and the display driver 200 and the pad portion may be disposed in the non-display area NDA.

The display driver 200 may output signals and voltages for driving the display panel 100. The display driver 200 may supply data voltages to data lines. The display driver 200 may supply a power voltage to a power line and supply a gate control signal to the gate driver. The display driver 200 may receive a sensing signal through a read-out line. The display driver 200 may be formed of an integrated circuit (IC) and may be packaged on the display panel 100 in any one of a variety of methods including a chip on glass (COG) method, a chip on plastic (COP) method or an ultrasonic bonding method. For example, the display driver 200 may be disposed in the sub-area SBA, and may overlap the main area MA in the thickness direction (Z-axis direction) by bending of the sub-area SBA. For another example, the display driver 200 may be packaged on the circuit board 300.

The circuit board 300 may be attached onto the pad portion of the display panel 100 using an anisotropic conductive film (ACF). Lead lines of the circuit board 300 may electrically be connected to the pad portion of the display panel 100. The circuit board 300 may be a flexible printed circuit board, a printed circuit board or a flexible film such as a chip on film.

The touch driver 400 may be packaged on the circuit board 300. The touch driver 400 may be connected to a touch sensing unit of the display panel 100. The touch driver 400 may supply a touch driving signal to a plurality of touch electrodes of the touch sensing unit, and may sense a change amount in capacitance between the plurality of touch electrodes. For example, the touch driving signal may be a pulse signal having a predetermined frequency. The touch driver 400 may calculate an input and input coordinates based on the change amount in capacitance between the plurality of touch electrodes, for example, to perform an operation corresponding to the input and input coordinates. The touch driver 400 may be formed of an integrated circuit (IC).

The power supply unit 500 may be disposed on the circuit board 300 to supply the power voltage to the display driver 200 and the display panel 100. For example, the power supply unit 500 may generate a driving voltage to supply the driving voltage to a driving voltage line and a common voltage to be supplied to a common electrode that is provided in common to a plurality of light emitting elements. For example, the driving voltage may be a high potential voltage for driving the light emitting element, and the common voltage may be a low potential voltage for driving the light emitting element. The power supply unit 500 may generate an initialization voltage to be supplied to an initialization voltage line, generate a reference voltage to be supplied to a reference voltage line, generate a bias voltage to be supplied to a bias voltage line, and generate a reset voltage to be supplied to a reset voltage line.

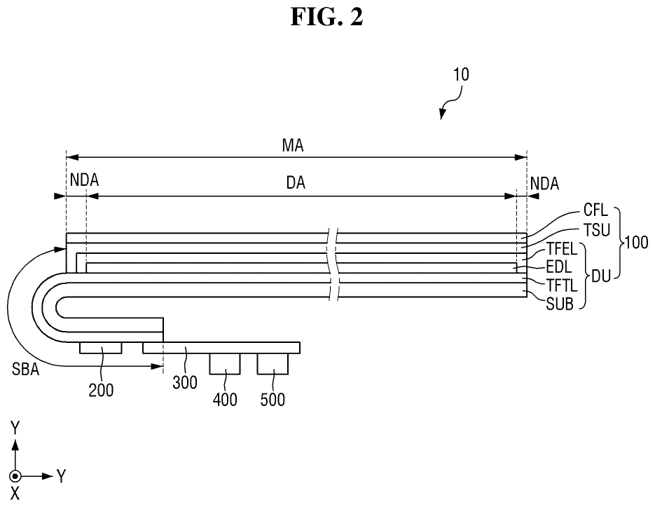

FIG. 2 is a cross-sectional view illustrating the display device 10 which is in a folded state according to one embodiment of the present disclosure.

Referring to FIG. 2, the display panel 100 may include a display unit DU, a touch sensing unit TSU, and a color filter layer CFL. The display unit DU may include a substrate SUB, a transistor layer TFTL, a light emitting element layer EDL, and an encapsulation layer TFEL. These layers may be sequentially arranged as stated or one or more layers may be arranged in a different sequence in another embodiment.

The substrate SUB may be a base substrate or a base member. The substrate SUB may be a flexible substrate capable of bending, folding, rolling and the like. For example, the substrate SUB may include a polymer resin such as polyimide (PI), but is not limited thereto. For another example, the substrate SUB may include a glass material or a metal material.

The transistor layer TFTL may be disposed on the substrate SUB. The transistor layer TFTL may include a plurality of thin film transistors to be included in a pixel and a fingerprint sensor. The transistor layer TFTL may further include gate lines, data lines, power lines, power lines, read-out lines, gate control lines, fan-out lines connecting the display driver 200 with the data lines, and lead lines connecting the display driver 200 with the pad portion. Each of the transistors may include a semiconductor area, a source electrode, a drain electrode, and a gate electrode. For example, when the gate driver is formed on one side of the non-display area NDA of the display panel 100, the gate driver may include transistors.

The transistor layer TFTL may be disposed in the display area DA, the non-display area NDA and the sub-area SBA. The transistors, the gate lines, the data lines, the power lines and the read-out lines of the transistor layer TFTL may be disposed in the display area DA. The gate control lines and fan-out lines of the transistor layer TFTL may be disposed in the non-display area NDA. The lead lines of the transistor layer TFTL may be disposed in the sub-area SBA.

The light emitting element layer EDL may be disposed on the transistor layer TFTL. The light emitting element layer EDL may include a light emitting element of a pixel, a light-receiving element of a fingerprint sensor, and a pixel defining layer for a pixel and a fingerprint sensor. The light emitting element may include a pixel electrode, a light emitting layer and a common electrode which are sequentially stacked to emit light. The light-receiving element may include a sensor electrode, a light-receiving layer and a common electrode which are sequentially stacked to receive light. The light emitting elements and the light receiving elements of the light emitting element layer EDL may be disposed in the display area DA.

For example, the light emitting layer may be an organic light emitting layer that includes an organic material. The light emitting layer may include a hole transporting layer, an organic light emitting layer and an electron transporting layer. When the pixel electrode receives a predetermined voltage through the transistor of the thin transistor layer TFTL and the common electrode receives a cathode voltage, holes may move to the organic light emitting layer through the hole transporting layer and electrons may move to the organic light emitting layer through the electron transporting layer. The holes and the electrons may combine in the organic light emitting layer to induce emission of light. For example, the pixel electrode may be an anode electrode and the common electrode may be a cathode electrode, but they are not limited thereto. In another example, the plurality of light emitting elements may include a quantum dot light emitting diode including a quantum dot light emitting layer, an inorganic light emitting diode including an inorganic semiconductor, or a micro light emitting diode.

The light receiving element may receive light and convert light energy into an electrical signal. When the finger of a user touches the display panel 100, the light emitted from the light emitting element may be reflected by the finger, and the light receiving element may receive the reflected light. The fingerprint of the finger has ridges and valleys that affect reflected light differently. A sensing signal of the fingerprint sensor that has received the light reflected by a ridge of the finger may be different from a sensing signal of the fingerprint sensor that has received the light reflected by a valley of the finger. A processor may generate sensing data by distinguishing a difference between the sensing signals, and may determine whether the ridge or the valley of the finger has been touched on the display panel 100 based on the sensing data. Therefore, the display device 10 may recognize the pattern of the user fingerprint based on the sensing data. For example, the light receiving element may be an organic photodiode, but is not limited thereto.

The encapsulation layer TFEL may cover an upper surface and sides of the light emitting element layer EDL, and may protect the light emitting element layer EDL. The encapsulation layer TFEL may include at least one inorganic layer and at least one organic layer which are intended to encapsulate the light emitting element layer EDL.

The touch sensing unit TSU may be disposed on the encapsulation layer TFEL. The touch sensing unit TSU may include a plurality of touch electrodes for sensing a touch of a user based on a change in capacitance and touch lines connecting the plurality of touch electrodes with the touch driver 400. The plurality of touch electrodes of the touch sensing unit TSU may be disposed in a touch sensor area that overlaps the display area DA. The touch lines of the touch sensing unit TSU may be disposed in a touch peripheral area that overlaps the non-display area NDA. For example, the touch sensing unit TSU may sense a touch of a user in a mutual capacitance manner or a self-capacitance manner.

In another example, the touch sensing unit TSU may be disposed on a separate substrate disposed on the display unit DU. In this case, the substrate supporting the touch sensing unit TSU may be a base member for encapsulating the display unit DU.

The color filter layer CFL may be disposed on the touch sensing unit TSU. The color filter layer CFL may include a plurality of color filters respectively corresponding to the plurality of emission areas. Each of the color filters may selectively transmit light of a particular wavelength, and may block or absorb light of one or more other wavelengths. The color filter layer CFL may absorb a portion of light incident from outside of the display device 10 to reduce reflective light due to external light. Therefore, the color filter layer CFL may prevent distortion of color due to the occurrence of external light reflection.

Because the color filter layer CFL is directly disposed on the touch sensing unit TSU, the display device 10 may not require a separate substrate for the color filter layer CFL. Therefore, the thickness of the display device 10 may be significantly reduced.

The sub-area SBA may be extended from one side of the main area MA. The sub-area SBA may include a flexible material capable of being subjected to bending, folding, rolling and the like. For example, when the sub-area SBA is bent, the sub-area SBA may overlap the main area MA in the thickness direction (Z-axis direction). The sub-area SBA may include a display driver 200, and a pad portion electrically connected to the circuit board 300.

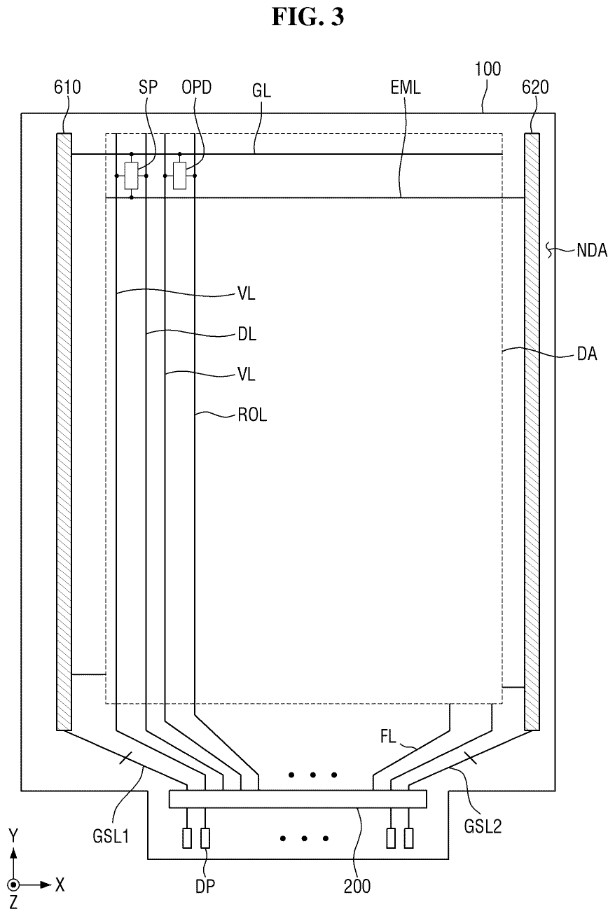

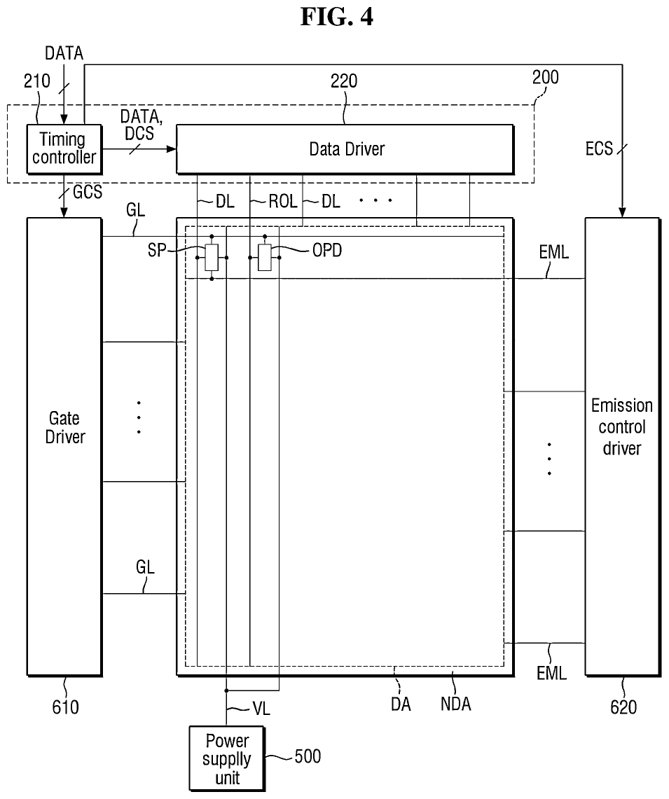

FIG. 3 is a plan view illustrating the display unit DU of the display device according to one embodiment, and FIG. 4 is a block diagram illustrating a display panel and a display driver according to one embodiment.

Referring to FIGS. 3 and 4, the display unit DU includes a display panel 100, which may include a display area DA and a non-display area NDA. The display area DA may include a plurality of pixels, a fingerprint sensor OPD, a power line VL, a data line DL, a read-out line ROL, a gate line GL, and an emission control line EML. Pixel SP is shown as a representative sample of the pixels of the display panel.

Each of the plurality of pixels SP may be connected to the gate line GL, the emission control line EML, the data line DL, and the power line VL. Each of the plurality of pixels SP may include at least one transistor, a light emitting element, and a capacitor.

Each of the plurality of fingerprint sensors OPD may be connected to the gate line GL, the power line VL and the read-out line ROL. Each of the plurality of fingerprint sensors OPD may include at least one transistor and a light receiving element.

The gate lines GL may extend in the X-axis direction, and may be spaced apart from each other in the Y-axis direction crossing the X-axis direction. The gate lines GL may sequentially supply gate signals to the pixels SP and the fingerprint sensors OPD.

The emission control lines EML may also extend in the X-axis direction, and may be spaced apart from each other in the Y-axis direction. The emission control lines EML may sequentially supply an emission signal to the pixels SP.

The data lines DL may extend in the Y-axis direction, and may be spaced apart from each other in the X-axis direction. The data lines DL may supply data voltages to respective ones of the pixels SP. The data voltages may determine luminance of light emitted from corresponding ones of the pixels SP.

The power lines VL may extend in the Y-axis direction, and may be spaced apart from each other in the X-axis direction. The power lines VL may supply the power voltage to the pixels SP and the fingerprint sensors OPD. The power voltage may be predetermined voltage such as a driving voltage, a common voltage, an initialization voltage, a reference voltage, a bias voltage or a reset voltage. The driving voltage may be a high potential voltage for driving the light emitting element, and the common voltage may be a low potential voltage for driving the light emitting element and the light receiving element.

The non-display area NDA may surround the display area DA. The non-display area NDA may include a gate driver 610, an emission control driver 620, fan-out lines FL, a first gate control line GSL1, and a second gate control line GSL2. The fan-out lines FL may extend from the display driver 200 to the display area DA. The fan-out lines FL may supply the data voltages received from the display driver 200 to the data line DLs, supply the power voltage received from the display driver 200 to the power line VL, and supply the sensing signal received from the read-out line ROL to the display driver 200. Therefore, the display driver 200 may drive the pixel SP and the fingerprint sensor OPD.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-area SBA may extend from one side of the non-display area NDA. The sub-area SBA may include a display driver 200 and a pad portion DP. The pad portion DP may be disposed to be more adjacent to an edge of one side of the sub-area SBA than the display driver 200. The pad portion DP may be electrically connected to the circuit board 300, for example, through an anisotropic conductive film (ACF).

Referring to FIGS. 3 and 4, the display driver 200 may include a timing controller 210 and a data driver 220. The timing controller 210 may receive digital video data DATA and timing signals from the circuit board 300. The timing controller 210 may generate a data control signal DCS based on the timing signals to control an operation timing of the data driver 220, may generate a gate control signal GCS to control an operation timing of the gate driver 610, and may generate an emission control signal ECS to control an operation timing of the emission control driver 620. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. The gate signals of the gate driver 610 may select pixels SP to which data voltages are supplied, and the selected pixels SP may receive the data voltages through the data lines DL. The data driver 220 may supply the sensing signal received through the read-out line ROL to the processor.

The power supply unit 500 may be disposed on the circuit board 300 to supply the power voltage to the display driver 200 and the display panel 100. The power supply unit 500 may generate the power supply voltage and supply the power voltage to the power line VL, and may generate the common voltage and supply the common voltage to the common electrode common to the pixels SP and the fingerprint sensors OPD. The power supply unit 500 may generate the initialization voltage and supply the initialization voltage to the initialization voltage line, generate the reference voltage and supply the reference voltage to the reference voltage line, generate the bias voltage and supply the bias voltage to the bias voltage line, and generate the reset voltage and supply the reset voltage to the reset voltage line.

The gate driver 610 may be disposed adjacent to one side of the display area DA or at one side of the non-display area NDA. The emission control driver 620 may be disposed adjacent to another (e.g., opposing) side of the display area DA or at another (e.g., opposing) side of the non-display area NDA, but the present disclosure is not limited thereto. As another example, the gate driver 610 and the emission control driver 620 may be disposed at different sides of the non-display area NDA, e.g., any one of one side and its opposing side of the non-display area NDA.

The gate driver 610 may include a plurality of transistors for generating gate signals based on the gate control signal GCS. The emission control driver 620 may include a plurality of transistors for generating emission signals based on the emission control signal ECS. For example, the transistors of the gate driver 610 and the transistors of the emission control driver 620 may be formed on the same layer as the transistors of the respective pixels SP. The gate driver 610 may supply the gate signals to the gate lines GL, and the emission control driver 620 may supply the emission signals to the emission control lines EML.

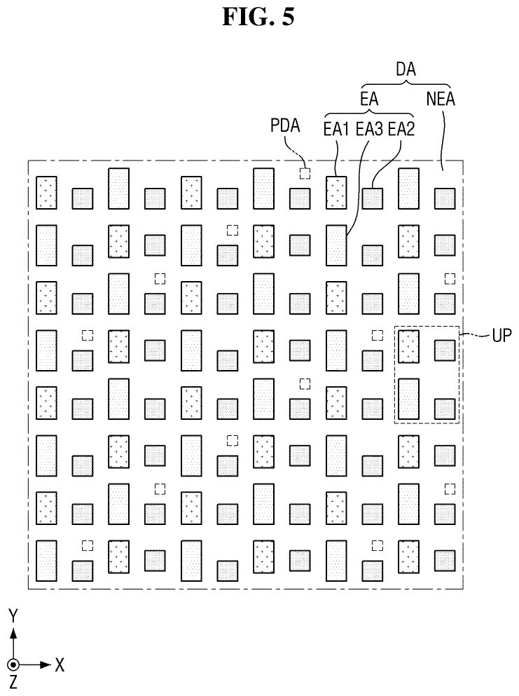

FIG. 5 is a plan view illustrating emission areas and sensor areas of a display device according to one embodiment.

Referring to FIG. 5, the display area DA may include emission areas EA and a non-emission area NEA. The emission areas EA may emit light of the light emitting elements. As shown, the light emitting elements may not be disposed in the non-emission area NEA. The non-emission area NEA may include sensor areas PDA spaced apart from each other with at least one emission area EA interposed therebetween. The emission areas EA may include first to third emission areas EA1, EA2 and EA3. For example, the first emission area EA1 may emit light of a first color (e.g., red light), the second emission area EA2 may emit light of a second color (e.g., green light), and the third emission area EA3 may emit light of a third color (e.g., blue light). In other embodiments, the first to third colors may correspond to a different combination of colors of light. In one embodiment, the first to third emission areas EA1 to EA3 may be considered to be sub-pixels.

As further shown in FIG. 5, one unit pixel UP may include one first emission area EA1, two second emission areas EA2 and one third emission area EA3 that collectively emit light that represent a gray scale of a predetermined value (e.g., a color of light produced from the combination of light from the emission areas), but the configuration of the unit pixel UP is not limited thereto. For example, a white gray scale value may be represented based on a combination of light emitted from one first emission area EA1, light emitted from two second emission areas EA2, and light emitted from one third emission area EA3.

The areas of the first to third emission areas EA1, EA2 and EA3 may be different of different sizes from one another. For example, the area of the third emission area EA3 may be greater than that of the first emission area EA1, and the area of the first emission area EA1 may also be greater than that of the second emission area EA2. In one embodiment, the areas of the first to third emission areas EA1, EA2 and EA3 may be the same as one another.

The sensor area PDA may be placed at predetermined locations within the display area DA. For example, the sensor area PDA may be surrounded by first to third emission areas EA1, EA2 and EA3. The sensor area PDA may be adjacent to the first or third emission area EA1 or EA3 in the X-axis direction, and may be adjacent to the second emission area EA2 in the Y-axis direction. The sensor areas PDA may be spaced apart from each other, with at least one emissive area EA interposed therebetween. The sensor area PDA may receive light reflected by a finger or stylus.

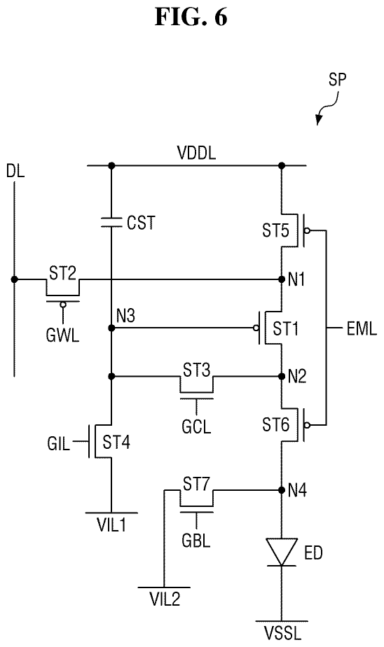

FIG. 6 is a circuit view illustrating a circuit diagram of the pixel SP of a display device according to one embodiment.

Referring to FIG. 6, the pixel SP may be connected to a first gate line GWL, a second gate line GCL, a third gate line GIL, a fourth gate line GBL, an emission control line EML, a data line DL, a driving voltage line VDDL, a first initialization voltage line VIL1, a second initialization voltage line VIL2, and a low potential line VSSL. One or more of these lines may also be coupled to the fingerprint sensor as described in greater detail below.

The pixel SP may include a light emitting element ED and a pixel circuit for driving the light emitting element ED. The pixel circuit may include a plurality of transistors and at least one capacitor. For example, the pixel circuit may include first to seventh transistors ST1, ST2, ST3, ST4, ST5, ST6 and ST7 and a capacitor CST.

The first transistor ST1 may be a driving transistor which controls a driving current supplied to the light emitting element ED. The first transistor ST1 may include a gate electrode, a first electrode, and a second electrode. The gate electrode of the first transistor ST1 may be connected to a third node N3, the first electrode of the first transistor ST1 may be connected to a first node N1, and the second electrode of the first transistor ST1 may be connected to a second node N2. For example, the first electrode of the first transistor ST1 may be a source electrode and the second electrode may be a drain electrode, but the present disclosure is not limited thereto.

The first transistor ST1 may control a source-drain current Isd (hereinafter, referred to as “driving current”) in accordance with the data voltage applied to the gate electrode. The driving current Isd flowing through a channel of the first transistor ST1 may be proportional to a square of a difference between a voltage Vsg between the source electrode and the gate electrode of the first transistor ST1 and a threshold voltage Vth, e.g., Isd=k×(Vsg−Vth)². In this case, k denotes a proportional coefficient determined by the structure and physical characteristics of the first transistor ST1, Vsg denotes a source-gate voltage of the first transistor ST1, and Vth denotes the threshold voltage of the first transistor ST1.

The light emitting element ED may emit light based on the driving current Isd. The amount or luminance of light emitted from the light emitting element ED may be proportional to the magnitude of the driving current Isd. The light emitting element ED may include a first electrode, a second electrode and a light emitting layer disposed between the first electrode and the second electrode. The first electrode of the light emitting element ED may be connected to a fourth node N4. The first electrode of the light emitting element ED may be connected to a second electrode of the sixth transistor ST6 and a first electrode of the seventh transistor ST7 through the fourth node N4. For example, the first electrode of the light emitting element ED may be an anode electrode or a pixel electrode, and the second electrode thereof may be a cathode electrode or a common electrode, but the present disclosure is not limited thereto.

The second transistor ST2 may be turned on by a first gate signal of the first gate line GWL, to electrically connect the data line DL with the first node N1 that is the first electrode of the first transistor ST1. The second transistor ST2 may be turned on based on the first gate signal to supply a data voltage to the first node N1. A gate electrode of the second transistor ST2 may be connected to the first gate line GWL, a first electrode of the second transistor ST2 may be connected to the data line DL, and a second electrode of the second transistor ST2 may be connected to the first node N1. The second electrode of the second transistor ST2 may be connected to the first electrode of the first transistor ST1 and a second electrode of the fifth transistor ST5 through the first node N1. For example, the first electrode of the second transistor ST2 may be a source electrode, and the second electrode of the second transistor ST2 may be a drain electrode, but the present disclosure is not limited thereto. The first gate line GWL may also be coupled to the third sensor transistor PT3 as described below.

The third transistor ST3 may be turned on by a second gate signal of the second gate line GCL to electrically connect the second node N2, which is the second electrode of the first transistor ST1, with the third node N3 that is coupled to the gate electrode of the first transistor ST1. A first electrode of the third transistor ST3 may be connected to the first second electrode of the first transistor ST1 and the first electrode of the sixth transistor ST6 through the second node N2. The second electrode of the third transistor ST3 may be connected to the gate electrode of the first transistor ST1, a first electrode of the fourth transistor ST4 and a first capacitor electrode of the capacitor CST through the third node N3. For example, the first electrode of the third transistor ST3 may be a drain electrode, and the second electrode of the third transistor ST3 may be a source electrode, but the present disclosure is not limited thereto.

The fourth transistor ST4 may be turned on by a third gate signal of the third gate line GIL to electrically connect the third node N3, which is coupled to the gate electrode of the first transistor ST1, with the first initialization voltage line VIL1. The fourth transistor ST4 may be turned on based on the third gate signal to discharge the gate electrode of the first transistor ST1 with a first initialization voltage. A gate electrode of the fourth transistor ST4 may be connected to the third gate line GIL, a first electrode of the fourth transistor ST4 may be connected to the third node N3, and a second electrode of the fourth transistor ST4 may be connected to the first initialization voltage line VIL1. The first electrode of the fourth transistor ST4 may be connected to the gate electrode of the first transistor ST1, the second electrode of the third transistor ST3 and the first capacitor electrode of the capacitor CST through the third node N3. For example, the first electrode of the fourth transistor ST4 may be a drain electrode, and the second electrode of the fourth transistor ST4 may be a source electrode, but the present disclosure is not limited thereto.

The fifth transistor ST5 may be turned on by the emission signal of the emission control line EML to electrically connect the driving voltage line VDDL with the first node N1, that is coupled to the source electrode of the first transistor ST1. A gate electrode of the fifth transistor ST5 may be connected to the emission control line EML, a first electrode of the fifth transistor ST5 may be connected to the driving voltage line VDDL, and a second electrode of the fifth transistor ST5 may be connected to the first node N1. The second electrode of the fifth transistor ST5 may be connected to the first electrode of the first transistor ST1 and the second electrode of the second transistor ST2 through the first node N1. For example, the first electrode of the fifth transistor ST5 may be a source electrode, and the second electrode of the fifth transistor ST5 may be a drain electrode, but the present disclosure is not limited thereto.

The sixth transistor ST6 may be turned on by the emission signal of the emission control line EML to electrically connect the second node N2, which is the second electrode of the first transistor ST1, with the fourth node N4 that is coupled to the first electrode of the light emitting element ED. A gate electrode of the sixth transistor ST6 may be connected to the emission control line EML, the first electrode of the sixth transistor ST6 may be connected to the second node N2, and the second electrode of the sixth transistor ST6 may be connected to the fourth node N4. The second electrode of the sixth transistor ST6 may be connected to the first electrode of the light emitting element ED and the first electrode of the seventh transistor ST7 through the fourth node N4. For example, the first electrode of the sixth transistor ST6 may be a source electrode, and the second electrode of the sixth transistor ST6 may be a drain electrode, but the present disclosure is not limited thereto.

In operation, when the fifth transistor ST5, the first transistor ST1 and the sixth transistor ST6 are all turned on, the driving current Isd may be supplied to the light emitting element ED.

The seventh transistor ST7 may be turned on by a fourth gate signal of the fourth gate line GBL to electrically connect the second initialization voltage line VIL2 with the fourth node N4, that is coupled to the first electrode of the light emitting element ED. The seventh transistor ST7 may be turned on based on the fourth gate signal to discharge the first electrode of the light emitting element ED with a second initialization voltage. A gate electrode of the seventh transistor ST7 may be connected to the fourth gate line GBL, the first electrode of the seventh transistor ST7 may be connected to the fourth node N4, and a second electrode of the seventh transistor ST7 may be connected to the second initialization voltage line VIL2. The second electrode of the seventh transistor ST7 may be connected to the first electrode of the light emitting element ED and the second electrode of the sixth transistor ST6 through the fourth node N4.

Each of the first transistor ST1, the second transistor ST2, the fifth transistor ST5, the sixth transistor ST6 and the seventh transistor ST7 may include a silicon-based semiconductor area. For example, each of the first transistor ST1, the second transistor ST2, the fifth transistor ST5, the sixth transistor ST6 and the seventh transistor ST7 may include a semiconductor area made of low temperature polycrystalline silicon (LTPS). The semiconductor area made of low temperature polycrystalline silicon may have high electron mobility and excellent turn-on characteristics. Therefore, each of the pixels SP of the display device 10 includes the first transistor ST1, the second transistor ST2, the fifth transistor ST5, the sixth transistor ST6 and the seventh transistor ST7, which have excellent turn-on characteristics, thereby stably and efficiently driving the plurality of pixels SP.

Each of the first transistor ST1, the second transistor ST2, the fifth transistor ST5, the sixth transistor ST6 and the seventh transistor ST7 may be p-type transistors. For example, each of the first transistor ST1, the second transistor ST2, the fifth transistor ST5, the sixth transistor ST6 and the seventh transistor ST7 may output a current flowing into the source electrode, to the second electrode based on a gate low voltage applied to their gate electrodes.

Each of the third transistor ST3 and the fourth transistor ST4 may include an oxide-based semiconductor area. For example, each of the third transistor ST3 and the fourth transistor ST4 may have a coplanar structure in which a gate electrode is disposed on an oxide-based semiconductor area. The transistor having the coplanar structure has excellent leakage current characteristics and enables low frequency driving, thereby reducing power consumption. Therefore, the display device 10 includes the third transistor ST3 and the fourth transistor ST4, which have excellent leakage current characteristics, thereby preventing a leakage current from flowing into the pixel and stably maintaining a voltage inside the pixel.

Each of the third transistor ST3 and the fourth transistor ST4 may be n-type transistors. For example, each of the third transistor ST3 and the fourth transistor ST4 may output a current flowing into the first electrode, to the second electrode based on a gate high voltage applied to the gate electrode.

The capacitor CST may be connected between the third node N3, which is coupled to the gate electrode of the first transistor ST1, and the driving voltage line VDDL. For example, the first capacitor electrode of the capacitor CST may be connected to the third node N3, and a second capacitor electrode of the capacitor CST may be connected to the driving voltage line VDDL, so that a potential difference between the driving voltage line VDDL and the gate electrode of the first transistor ST1 may be maintained.

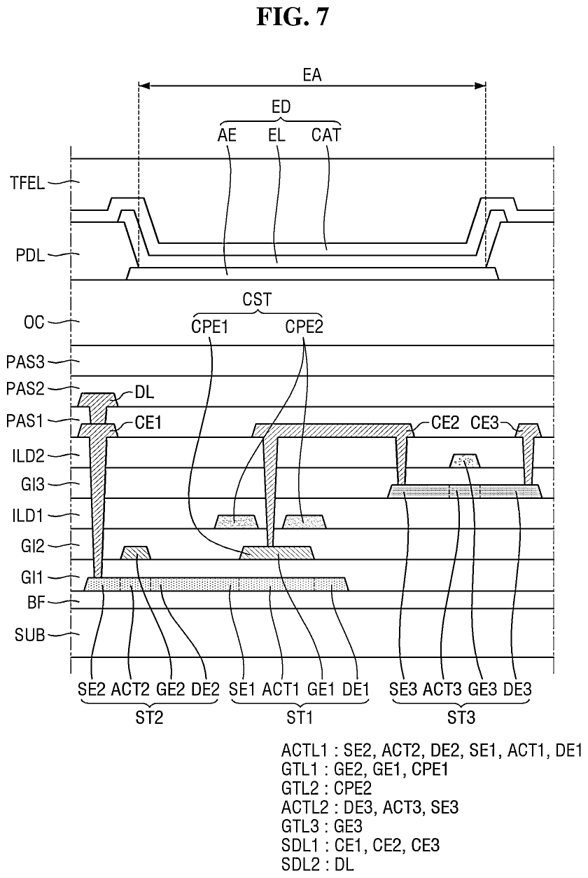

FIG. 7 is a cross-sectional view illustrating the pixel SP of the display device 10 according to one embodiment.

Referring to FIG. 7, the display panel 100 may include in sequential order a substrate SUB, a buffer layer BF, a first active layer ACTL1, a first gate insulating layer GI1, a first gate layer GTL1, a second gate insulating layer GI2, a second gate layer GTL2, a first interlayer insulating layer ILD1, a second active layer ACTL2, a third interlayer insulating layer GI3, a third gate layer GTL3, a second interlayer insulating layer ILD2, a first source metal layer SDL1, a first passivation layer PAS1, a second source metal layer SDL2, a second passivation layer PAS2, a third passivation layer PAS3, a planarization layer OC, a pixel defining layer PDL, a light emitting element ED, and an encapsulation layer TFEL. In other embodiments, one or more of the aforementioned features may be arranged in a different order or may be omitted. In still other embodiments, one or more additional layers may be included in the pixel SP.

The substrate SUB may be a base substrate or a base member. In one embodiment, the substrate may be a flexible substrate capable of bending, folding, rolling or the like. For example, the substrate SUB may include a polymer resin such as polyimide (PI), but is not limited thereto. For another example, the substrate SUB may include a glass material or a metal material.

The buffer layer BF may be disposed on the substrate SUB. For example, the buffer layer BF may include an inorganic layer capable of preventing permeation of air or moisture from permeating into the interior portion of the pixel SP. For example, the buffer layer BF may include a plurality of inorganic layers that are alternately stacked.

The first active layer ACTL1 may be disposed on the buffer layer BF. The first active layer ACTL1 may include a semiconductor (e.g., silicon-based) material. For example, the first active layer ACTL1 may be formed of low temperature polycrystalline silicon (LTPS). The first active layer ACTL1 may include a semiconductor area ACT1, a first electrode SE1 and a second electrode DE1 of the first transistor ST1, and a semiconductor area ACT2, a first electrode SE2 and a second electrode DE2 of the second transistor ST2.

The first gate insulating layer GI1 may be disposed on the first active layer ACTL1. The first gate insulating layer GI1 may insulate the first active layer ACTL1 from the first gate layer GTL1.

The first gate layer GTL1 may be disposed on the first gate insulating layer GI1. The first gate layer GTL1 may include a gate electrode GE1 of the first transistor ST1, a gate electrode GE2 of the second transistor ST2, and a first capacitor electrode CPE1. The gate electrode GE1 of the first transistor ST1 may be a portion of the first capacitor electrode CPE1, and the gate electrode GE2 of the second transistor ST2 may be a portion of the first gate line GWL.

The second gate insulating layer GI2 may be disposed on the first gate layer GTL1. The second gate insulating layer GI2 may insulate the first gate layer GTL1 from the second gate layer GTL2.

The second gate layer GTL2 may be disposed on the second gate insulating layer GI2. The second gate layer GTL2 may include a second capacitor electrode CPE2. The second capacitor electrode CPE2 may overlap the first capacitor electrode CPE1.

The first interlayer insulating layer ILD1 may be disposed on the second gate layer GTL2. The first interlayer insulating layer ILD1 may insulate the second gate layer GTL2 from a second active layer ACTL2.

The second active layer ACTL2 may be disposed on the first interlayer insulating layer ILD1. The second active layer ACTL2 may include an oxide-based material. The second active layer ACTL2 may include a semiconductor area ACT3, a first electrode DE3 and a second electrode SE3 of the third transistor ST3.

The third gate insulating layer GI3 may be disposed on the second active layer ACTL2. The third gate insulating layer GI3 may insulate the second active layer ACTL2 from the third gate layer GTL3.

The third gate layer GTL3 may be disposed on the third gate insulating layer GI3. The third gate layer GTL3 may include a gate electrode GE3 of the third transistor ST3. The gate electrode GE3 of the third transistor ST3 may be a portion of the second gate line GCL.

The second interlayer insulating layer ILD2 may be disposed on the third gate layer GTL3. The second interlayer insulating layer ILD2 may insulate the third gate layer GTL3 from the first source metal layer SDL1.

The first source metal layer SDL1 may be disposed on the second interlayer insulating layer ILD2. The first source metal layer SDL1 may include first to third connection electrodes CE1, CE2 and CE3. The first connection electrode CE1 may electrically connect the data line DL with the first electrode SE2 of the second transistor ST2. The second connection electrode CE2 may electrically connect the first capacitor electrode CPE1 with the second electrode SE3 of the third transistor ST3. The third connection electrode CE3 may electrically connect the first electrode DE3 of the third transistor ST3 with the second electrode DE1 of the first transistor ST1.

The first passivation layer PAS1 may be disposed on the first source metal layer SDL1. The first passivation layer PAS1 may insulate the first source metal layer SDL1 from the second source metal layer SDL2.

The second source metal layer SDL2 may be disposed on the first passivation layer PAS1. The second source metal layer SDL2 may include a data line DL. The driving voltage line VDDL, the first initialization voltage line VIL1, the second initialization voltage line VIL2 and the low potential line VSSL may be disposed on the second source metal layer SDL2.

The second passivation layer PAS2 may be disposed on the second source metal layer SDL2. The second passivation layer PAS2 may insulate the second source metal layer SDL2 from the third source metal layer.

The third passivation layer PAS3 may be disposed on the second passivation layer PAS2. The planarization layer OC may be disposed on the third passivation layer PAS3. The planarization layer OC may planarize an upper end of the transistor layer TFTL. The planarization layer OC may include an organic insulating material such as polyimide (PI).

The pixel defining layer PDL may be disposed on the planarization layer OC. The pixel defining layer PDL may define a plurality of emission areas EA. The pixel defining layer PDL may include, for example, an organic insulating material such as polyimide (PI).

The light emitting element ED may include a first (anode) electrode AE, a light emitting layer EL and a second (cathode) electrode CAT. The first electrode AE may be disposed on the planarization layer OC. The first electrode AE may overlap one of the plurality of emission areas EA defined by the pixel defining layer PDL. The first electrode AE may receive a driving current from a pixel circuit of the pixel SP.

The light emitting layer EL may be disposed on the first electrode AE. For example, the light emitting layer EL may be an organic light emitting layer made of an organic material, but is not limited thereto. In the case that the light emitting layer EL corresponds to the organic light emitting layer, when the pixel circuit of the pixel SP applies a predetermined voltage to the first electrode AE and the second electrode CAT receives the common voltage or the cathode voltage, holes and electrons may move to the organic light emitting layer EL through the hole transporting layer and the electron transporting layer. When the holes and electrons combine with each other in the organic light emitting layer EL, the pixel SP may induce the emission of light.

The second electrode CAT may be disposed on the light emitting layer EL. For example, the second electrode CAT may be implemented in the form of an electrode that is common to a plurality of pixels SP without being distinguished for each of the plurality of pixels SP. The second electrode CAT may be disposed on the light emitting layer EL in the plurality of emission areas, and may be disposed on the pixel defining layer PDL in an area except the plurality of emission areas.

The encapsulation layer TFEL may be disposed on the second electrode CAT to cover the plurality of light emitting elements ED. The encapsulation layer TFEL may include at least one inorganic layer to prevent oxygen or moisture from permeating into the plurality of light emitting elements ED. The encapsulation layer TFEL may include at least one organic layer to protect the plurality of light emitting elements ED from particles such as dust.

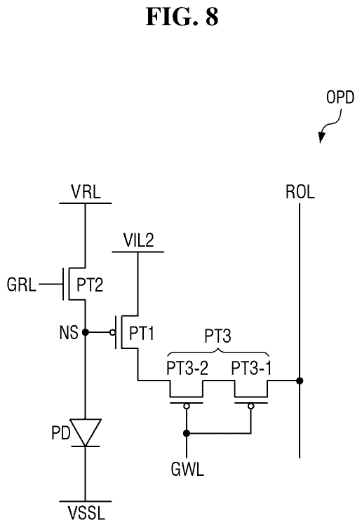

FIG. 8 is a circuit view illustrating the fingerprint sensor OPD of the display device 10 according to one embodiment.

Referring to FIG. 8, the fingerprint sensor OPD may be connected to the first gate line GWL, a reset signal line GRL, a reset voltage line VRL, the second initialization voltage line VIL2 and the read-out line ROL. The fingerprint sensor OPD may include a light receiving element PD and a sensor circuit for driving the light receiving element PD. The sensor circuit may include first to third sensor transistors PT1, PT2 and PT3.

The first sensor transistor PT1 may include a gate electrode, a first electrode and a second electrode. The gate electrode of the first sensor transistor PT1 may be connected to a sensor node NS, the first electrode of the first sensor transistor PT1 may be connected to the third sensor transistor PT3, and the second electrode of the first sensor transistor PT1 may be connected to the second initialization voltage line VIL2. The first sensor transistor PT1 may control a source-drain current Isd (hereinafter, referred to as a “sensing current”) based on a voltage of the sensor node NS, which is a first electrode of the light receiving element PD. The sensing current flowing through a channel of the first sensor transistor PT1 may be proportional to a square of a difference between a voltage Vsg between a source electrode and a gate electrode of the first sensor transistor PT1 and a threshold voltage Vth, e.g., Isd=k′×(Vsg−Vth) 2. In this case, k′ denotes a proportional coefficient determined by the structure and physical characteristics of the first sensor transistor PT1, Vsg denotes a source-gate voltage of the first sensor transistor PT1, and Vth denotes the threshold voltage of the first sensor transistor PT1. The first electrode of the first sensor transistor PT1 may be a source electrode and the second electrode of the first sensor transistor PT1 may be a drain electrode, but they are not limited thereto.

The second sensor transistor PT2 (or reset transistor) may be turned on by a reset signal of the reset signal line GRL, to supply the reset voltage to the sensor node NS. A gate electrode of the second sensor transistor PT2 may be connected to the reset signal line GRL, a first electrode of the second sensor transistor PT2 may be connected to the reset voltage line VRL, and a second electrode of the second sensor transistor PT2 may be connected to the sensor node NS. The second electrode of the second sensor transistor PT2 may be connected to the first electrode of the light receiving element PD and the gate electrode of the first sensor transistor PT1 through the sensor node NS. The first electrode of the second sensor transistor PT2 may be a drain electrode and the second electrode of the second sensor transistor PT2 may be a source electrode, but they are not limited thereto.

The third sensor transistor PT3 may be turned on by the first gate signal of the first gate line GWL, to electrically connect the first electrode of the first sensor transistor PT1 with the read-out line ROL. The third sensor transistor PT3 may include a first sensor transistor PT3-1 and a second sensor transistor PT3-2, which are connected in series. The first sensor transistor PT3-1 and the second sensor transistor PT3-2 may be connected in series between the first electrode of the first sensor transistor PT1 and the read-out line ROL. A gate electrode of the first sensor transistor PT3-1 and a gate electrode of the second sensor transistor PT3-2 may be integrally formed and electrically connected to the first gate line GWL. A first electrode of the first sensor transistor PT3-1 may be connected to the read-out line ROL, and a second electrode of the second sensor transistor PT3-2 may be connected to the first electrode of the first sensor transistor PT1. A second electrode of the first sensor transistor PT3-1 and a first electrode of the second sensor transistor PT3-2 may be integrally formed. The first electrode of each of the first sensor transistor PT3-1 and the second sensor transistor PT3-2 may be a source electrode and the second electrode thereof may be a drain electrode, but they are not limited thereto.

The light receiving element PD may recognize a portion (e.g., ridge or valley) of the pattern of a user fingerprint based on light reflected from a user's finger. The first electrode of the light receiving element PD may be connected to the sensor node NS that is the gate electrode of the first sensor transistor PT1. The second electrode of the light receiving element PD may be connected to the low potential line VSSL. The second electrode of the light receiving element PD may receive a low potential voltage from the low potential line VSSL.

In operation, when the user's finger touches the display panel 100, the light receiving element PD may receive light reflected by the ridge or valley of the finger. The light output from the light emitting element ED may be reflected by the ridge or valley of the finger, and the reflected light may reach the light receiving element PD. The light receiving element PD may convert energy of the reflected light to an electrical signal (current or voltage) formed between the first electrode and the second electrode. The converted electrical signal may flow from the sensor node NS to the low potential line VSSL. For example, when the light receiving element PD receives light, an electric field is formed between the first electrode and the second electrode of the light receiving element PD. As a result, current may flow to the light receiving element PD in proportion to the quantity of light, and the voltage of the sensor node NS may be reduced. When the light receiving element PD receives the light, the voltage of the sensor node NS may be reduced, and the magnitude of the sensing current (or the source-drain current) of the first sensor transistor PT1 may be reduced. The sensing current of the first sensor transistor PT1 may be applied to the display driver 200 as a sensing signal through the third sensor transistor PT3 and the read-out line ROL.

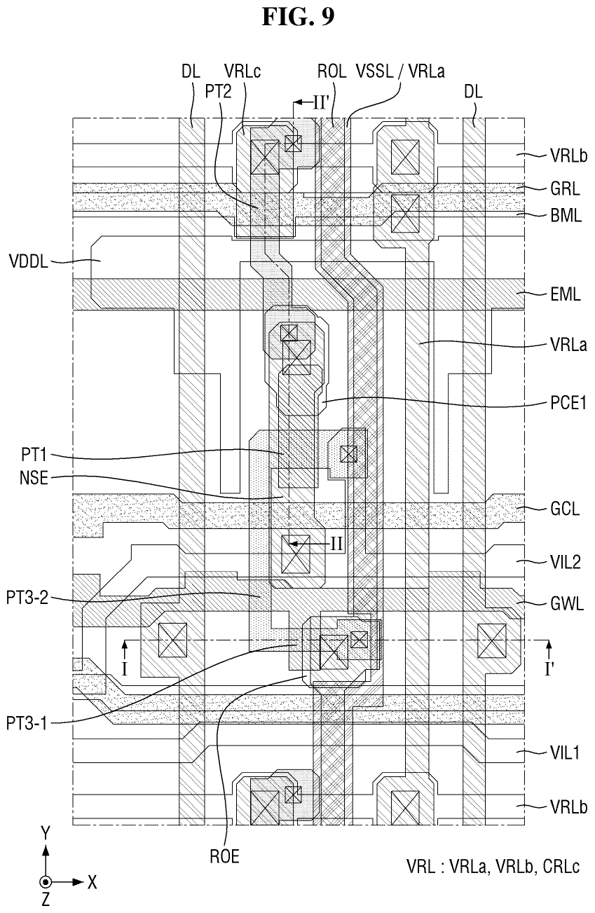

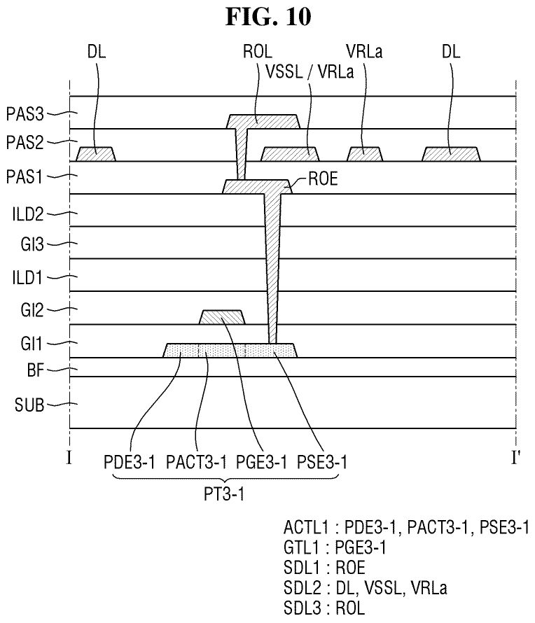

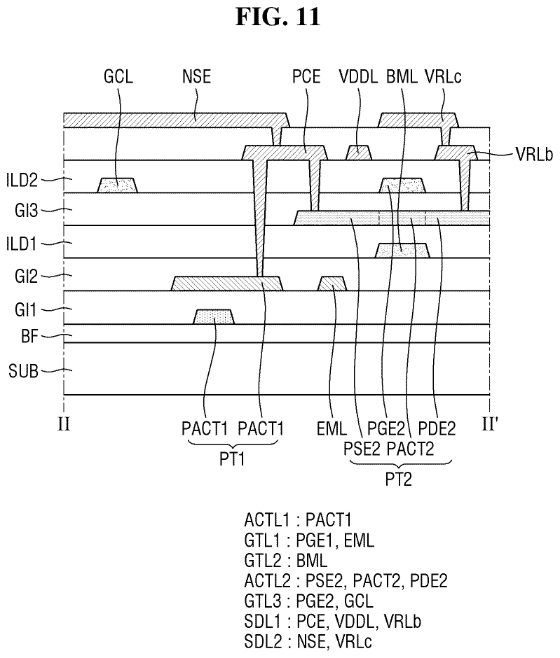

FIG. 9 is a layout view illustrating the fingerprint sensor OPD of the display device 10 according to one embodiment. FIG. 10 is a cross-sectional view taken along line I-I′ of FIG. 9 according to an embodiment. FIG. 11 is a cross-sectional view taken along line II-II′ of FIG. 9 according to an embodiment. Hereinafter, the same elements as those described above will be briefly described or omitted.

Referring to FIGS. 9 to 11, the fingerprint sensor OPD may be connected to the first gate line GWL, the reset signal line GRL, the reset voltage line VRL, the second initialization voltage line VIL2 and the read-out line ROL. As will be discussed in greater detail below a power line may shield the read-out line from the reset signal line GRL and/or one or more other lines, including ones coupled to the pixel SP such as the data line DL. This may increase sensitivity of the fingerprint sensor OPD. The first gate line GWL may be disposed on the first gate layer GTL1 and extend in the X-axis direction. The first gate line GWL may supply the first gate signal to the third sensor transistor PT3.

The reset signal line GRL may be disposed in the third gate layer GTL3 and extend in the X-axis direction. The reset signal line GRL may supply the reset signal to the second sensor transistor PT2 in order to reset the sensor node NS.

The reset voltage line VRL may supply the reset voltage to a first electrode PDE2 of the second sensor transistor PT2. The reset voltage line VRL may include a first portion VRLa, a second portion VRLb, and a third portion VRLc. The first portion VRLa may form a portion of the power line that shield the read-out line in accordance with one embodiment. In other embodiments, the power line may include low potential line VSSL. The first portion VRLa of the reset voltage line VRL may be disposed in the second source metal layer SDL2 and extend in the Y-axis direction. The first portion VRLa of the reset voltage line VRL may be disposed in parallel with the data line DL. The first portion VRLa of the reset voltage line VRL may be connected to the second portion VRLb.

The second portion VRLb of the reset voltage line VRL may be disposed in the first source metal layer SDL1 and extend in the X-axis direction. The second portion VRLb of the reset voltage line VRL may be connected between the first portion VRLa and the third portion VRLc.

The third portion VRLc of the reset voltage line VRL may be disposed in the second source metal layer SDL2 to overlap a semiconductor area PACT2 of the second sensor transistor PT2. The third portion VRLc of the reset voltage line VRL may be connected to the first electrode PDE2 of the second sensor transistor PT2 to supply the reset voltage. The third portion VRLc of the reset voltage line VRL may block light incident from an upper portion of the second sensor transistor PT2.

The second initialization voltage line VIL2 may be disposed on the first source metal layer SDL1 and extend in the X-axis direction. A portion of the second initialization voltage line VIL2 may protrude in the Y-axis direction and may be connected to the second electrode of the first sensor transistor PT1. The second initialization voltage line VIL2 may supply the second initialization voltage to the second electrode of the first sensor transistor PT1.

The driving voltage line VDDL may be disposed on the first source metal layer SDL1 and extend in the X-axis direction. The driving voltage line VDDL may be extended to the pixel SP, and may supply a driving voltage to the pixel SP.

The fingerprint sensor OPD may include first to third sensor transistors PT1, PT2 and PT3 and the light receiving element PD (e.g., see also FIG. 8). The first sensor transistor PT1 may include a semiconductor area PACT1 and a gate electrode PGE1. The semiconductor area PACT1 of the first sensor transistor PT1 may be disposed on the first active layer ACTL1, and the gate electrode PGE1 of the first sensor transistor PT1 may be disposed on the first gate layer GTL1. The gate electrode PGE1 of the first sensor transistor PT1 may overlap the semiconductor area PACT1 of the first sensor transistor PT1. The semiconductor area PACT1 of the first sensor transistor PT1 may include a silicon-based material. For example, the semiconductor area PACT1 of the first sensor transistor PT1 may include low temperature polycrystalline silicon (LTPS).

The gate electrode PGE1 of the first sensor transistor PT1 may be electrically connected to a sensor node electrode NSE of the second source metal layer SDL2 through a sensor connection electrode PCE disposed in the first source metal layer SDL1. The sensor node electrode NSE may correspond to the sensor node NS of FIG. 8 (which is reset by the reset signal line GRL), and may be electrically connected to the first electrode of the light receiving element PD. The gate electrode PGE1 of the first sensor transistor PT1 may be electrically connected to the second electrode PSE2 of the second sensor transistor PT2 disposed in the second active layer ACTL2 through the sensor connection electrode PCE.

The second sensor transistor PT2 may include a semiconductor area PACT2, a gate electrode PGE2, a first electrode PDE2 and a second electrode PSE2. The semiconductor area PACT2, the first electrode PDE2 and the second electrode PSE2 of the second sensor transistor PT2 may be disposed on the second active layer ACTL2, and the gate electrode PGE2 of the second sensor transistor PT2 may be disposed on the third gate layer GTL3. A gate electrode PGE3 of the second sensor transistor PT2 may be a portion of the reset signal line GRL of the third gate layer GTL3, and may overlap the semiconductor area PACT2 of the second sensor transistor PT2. For example, the semiconductor area PACT2 of the second sensor transistor PT2 may include an oxide-based material. A light blocking layer BML may be disposed on the second gate layer GTL2 to overlap the semiconductor area PACT2 of the second sensor transistor PT2. Therefore, the light blocking layer BML may block light incident from a lower portion of the second sensor transistor PT2.

The third sensor transistor PT3 may include a first transistor PT3-1 and a second transistor PT3-2, which are connected in series. The first transistor PT3-1 may include a semiconductor area PACT3-1, a gate electrode PGE3-1, a first electrode PSE3-1, and a second electrode PDE3-1. The semiconductor area PACT3-1, the first electrode PSE3-1 and the second electrode PDE3-1 of the first transistor PT3-1 may be disposed on the first active layer ACTL1, and the gate electrode PGE3-1 may be disposed on the first gate layer GTL1. The gate electrode PGE3-1 of the first transistor PT3-1 may overlap the semiconductor area PACT3-1 of the first transistor PT3-1. The semiconductor area PACT3-1 of the first transistor PT3-1 may include low temperature polycrystalline silicon (LTPS). Each of the gate electrode PGE3-1 of the first transistor PT3-1 and the gate electrode of the second transistor PT3-2 may be a portion of the first gate line GWL of the first gate layer GTL1.

The first electrode PSE3-1 of the first transistor PT3-1 may be electrically connected to the read-out line ROL of the third source metal layer SDL3 through a read-out electrode ROE of the first source metal layer SDL1. The third source metal layer SDL3 may be disposed on the second passivation layer PAS2. The read-out line ROL may extend in the Y-axis direction, and may overlap the power line formed from the low-potential line VSSL of the second source metal layer SDL2 or the first portion VRLa of the reset voltage line VRL. For example, a portion of the read-out lines ROL may overlap the low-potential line VSSL, and another portion of the read-out lines ROL may overlap the first portion VRLa of the reset voltage line VRL, but the present disclosure is not limited thereto. This arrangement of the power line may serve to shield the read-out line ROL from the data line and/or other lines as will be described in greater detail below.

More specifically, a direct current power line (such as the first portion VRLa of the reset power line VRL or the low potential line VSSL) may shield the read-out line ROL from the reset signal line GRL, the emission control line EML, the first gate line GWL and the second gate line GCL. The data line DL may be coupled to the reset signal line GRL, the emission control line EML, the first gate line GWL and the second gate line GCL, but the data line DL may not be coupled to the read-out line ROL by the direct current power line, e.g., the first portion VRLa of the reset voltage line VRL or the low potential line VSSL. Therefore, the display device 10 may include the direct current power line (such as the first portion VRLa of the reset voltage line VRL or the low potential line VSSL) which overlaps the read-out line ROL, thereby preventing coupling between the read-out line ROL and the data line DL and improving sensitivity of the fingerprint sensor OPD.

The effects of the present disclosure are not restricted to the one set forth herein. The above and other effects of the present disclosure will become more apparent to one of daily skill in the art to which the present disclosure pertains by referencing the claims. The embodiments may be combined to form additional embodiments.

What is claimed is:

1. A fingerprint sensor comprising:
a read-out line disposed on a substrate and extending in a first direction;
a light receiving element disposed on the read-out line;
a first sensor transistor configured to control a sensing current based on a voltage of a sensor node that is coupled to a first electrode of the light receiving element;
a second sensor transistor configured to supply a reset voltage to the sensor node based on a reset signal;
a third sensor transistor electrically connecting a first electrode of the first sensor transistor with the read-out line based on a gate signal; and
a power line disposed on a layer between the second sensor transistor and the read-out line and extending in the first direction, the power line overlapping the read-out line.

2. The fingerprint sensor of claim 1, wherein the power line is a direct current power line that comprises a reset voltage line configured to supply the reset voltage or a low potential line, connected to the second electrode of the light receiving element, to supply a low potential voltage.

3. The fingerprint sensor of claim 1, wherein:
a semiconductor area of each of the first sensor transistor and the third sensor transistor includes a silicon-based material, and
a semiconductor area of the second sensor transistor includes an oxide-based material.

4. The fingerprint sensor of claim 1, wherein the third sensor transistor includes a first transistor and a second transistor, which are connected in series between the first electrode of the first sensor transistor and the read-out line.

5. The fingerprint sensor of claim 1, further comprising:
a first active layer disposed on the substrate;
a first gate layer disposed on the first active layer;
a second gate layer disposed on the first gate layer;
a second active layer disposed on the second gate layer;
a third gate layer disposed on the second active layer;
a first source metal layer disposed on the third gate layer;
a second source metal layer disposed on the first source metal layer, comprising the power line; and
a third source metal layer disposed on the second source metal layer, comprising the read-out line.

6. The fingerprint sensor of claim 5, further comprising:
a read-out electrode disposed in the first source metal layer to electrically connect the read-out line with the third sensor transistor.

7. The fingerprint sensor of claim 5, further comprising:
a sensor node electrode disposed in the second source metal layer, corresponding to the sensor node; and
a sensor connection electrode disposed on the first source metal layer, electrically connecting a gate electrode of the first sensor transistor with the sensor node electrode.

8. The fingerprint sensor of claim 5, further comprising;
a reset voltage line including:
a first portion disposed in the second source metal layer and extending in the first direction,
a second portion disposed in the first source metal layer and connected to the first portion and extending in a second direction crossing the first direction, and
a third portion disposed in the second source metal layer and electrically connected between the second portion and the first electrode of the second sensor transistor.

9. The fingerprint sensor of claim 8, wherein the third portion of the reset voltage line overlaps a semiconductor area of the second sensor transistor.

10. The fingerprint sensor of claim 5, wherein:
a semiconductor area of the first sensor transistor is disposed in the first active layer, and
a semiconductor area of the second sensor transistor is disposed in the second active layer.

11. The fingerprint sensor of claim 5, further comprising:
a gate line disposed in the first gate layer to supply the gate signal; and
a reset signal line disposed in the third gate layer to supply the reset signal.

12. A fingerprint sensor comprising:
a light receiving element disposed on a substrate;
a first sensor transistor configured to control a sensing current based on a voltage of a sensor node that is coupled to a first electrode of the light receiving element;
a second sensor transistor configured to supply a reset voltage to the sensor node based on a reset signal;
a third sensor transistor electrically connecting a first electrode of the first sensor transistor with a read-out line based on a gate signal;
a first active layer disposed on the substrate and comprising a semiconductor area of the first sensor transistor;
a first gate layer disposed on the first active layer and comprising a gate electrode of the first sensor transistor;
a second gate layer disposed on the first gate layer;
a second active layer disposed on the second gate layer and comprising a semiconductor area of the second sensor transistor;
a third gate layer disposed on the second active layer and comprising a gate electrode of the second sensor transistor;
a first source metal layer disposed on the third gate layer;
a second source metal layer disposed on the first source metal layer and comprising the power line; and
a third source metal layer disposed on the second source metal layer and comprising the read-out line overlapped with the power line.

13. The fingerprint sensor of claim 12, wherein the power line is a direct current power line comprising a reset voltage line configured to supply the reset voltage or a low potential line connected to a second electrode of the light receiving element to supply a low potential voltage.

14. The fingerprint sensor of claim 12, wherein:
a semiconductor area of each of the first sensor transistor and the third sensor transistor includes a silicon-based material, and
a semiconductor area of the second sensor transistor includes an oxide-based material.

15. The fingerprint sensor of claim 12, wherein the third sensor transistor includes a first transistor and a second transistor, which are connected in series between the first electrode of the first sensor transistor and the read-out line.

16. The fingerprint sensor of claim 12, further comprising:
a read-out electrode disposed in the first source metal layer to electrically connect the read-out line with the third sensor transistor.

17. The fingerprint sensor of claim 12, further comprising:
a sensor node electrode disposed in the second source metal layer, corresponding to the sensor node; and
a sensor connection electrode disposed in the first source metal layer, electrically connecting the gate electrode of the first sensor transistor with the sensor node electrode.

18. A display device comprising:
a read-out line disposed on a substrate and extended in a first direction;
a fingerprint sensor disposed on the read-out line and comprising a light receiving element; and
a pixel including a light emitting element disposed on a same layer as the light receiving element, wherein the fingerprint sensor further comprises:
a first sensor transistor configured to control a sensing current based on a voltage of a sensor node that is a first electrode of the light receiving element;
a second sensor transistor configured to supply a reset voltage to the sensor node based on a reset signal;
a third sensor transistor electrically connecting a first electrode of the first sensor transistor with the read-out line based on a gate signal; and
a power line disposed on a layer between the second sensor transistor and the read-out line and extending in the first direction and overlapping the read-out line.

19. The display device of claim 18, further comprising:
a first active layer disposed on the substrate;
a first gate layer disposed on the first active layer;
a second gate layer disposed on the first gate layer;
a second active layer disposed on the second gate layer;
a third gate layer disposed on the second active layer;
a first source metal layer disposed on the third gate layer;
a second source metal layer disposed on the first source metal layer, comprising the power line; and
a third source metal layer disposed on the second source metal layer, comprising the read-out line.

20. The display device of claim 19, further comprising:
a data line disposed on the second source metal layer and extending in the first direction and configured to supply a data voltage to the pixel.

21. A fingerprint sensor comprising:
a read-out line;
a light receiving element;
a reset signal line to reset a sensor node; and
a power line which overlaps the read-out line to shield the read-out line from at least one signal line of a pixel disposed adjacent to the fingerprint sensor.

22. The fingerprint sensor of claim 21, wherein the at least one signal line is a data line of the pixel.

23. The fingerprint sensor of claim 21, wherein:
the reset signal line is coupled to a reset transistor, and
the power line is disposed on a layer between the reset transistor and the read-out line.

24. The fingerprint sensor of claim 21, wherein the power line is a low potential power line which couples the low potential to the light receiving element and a light emitting element of the pixel.

25. The fingerprint sensor of claim 21, wherein the power line is a portion of a reset power line coupled to a transistor coupled to the reset signal line.
